(19) United States
(12) Patent Application Publication
(10) Pub. No.: US 2006/0028225 A1
(43) Pub. Date: Feb. 9, 2006

(54) Process and a device for the calibration of a semiconductor component test system

(75) Inventor: Stephan von Appen, Munchen (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munich (DE)

(21) Appl. No.: 11/185,967

(22) Filed: Jul. 21, 2005

(30) Foreign Application Priority Data
Jul. 22, 2004 (DE) 10 2004 035556.8

(51) Int. Cl. G01R 31/02

(52) U.S. Cl. 324/757

(57) ABSTRACT

The invention relates to a device, in particular a probe card to be used for the testing of semi-conductor components, and/or a device, in particular a probe card, to be used in the calibration of a semi-conductor component test system and/or of a semi-conductor component test apparatus, a contact mechanism, in particular a wafer, as well as a process to be used in the calibration of a semi-conductor component test system and/or of a semi-conductor component test apparatus. The device and/or the probe card comprises a calibration device or parts of a calibration device, in particular a standard and/or reference comparator device and/or a standard and/or a reference driver device.

### CLAIM FOR PRIORITY

This application claims priority to German Application No. 10 2004 035556.8, filed Jul. 22, 2004, which is incorporated herein, in its entirety, by reference.

### TECHNICAL FIELD OF THE INVENTION

The invention relates to a process and device, in particular a probe card, to be used in the testing and calibration of semi-conductor components and test system.

### BACKGROUND OF THE INVENTION

Semi-conductor components, e.g. corresponding integrated (analog and/or digital) computing circuits, semi-conductor memory components such as function storage components (PLAs, PALs, etc.) and table memory components (e.g. ROMs and RAMs, in particular SRAMs and DRAMs), etc. are subjected—e.g. while in a semi-completed and/or a completed state—to numerous tests at several test stations.

For testing the semi-conductor components, an appropriate semi-conductor component test apparatus may be provided at each test station in question, which apparatus generates the test signals required for testing the semi-conductor components.

For instance the signals required for testing semi-conductor components still present on the corresponding wafer, may for instance be generated—at a first test station—by a test apparatus connected to a corresponding semi-conductor component test card (“probe card”) and sent to the relevant pads of the semi-conductor components by means of corresponding needle-shaped connections (“contact pins”) provided on the test card.

The signals, emitted by the semi-conductor components to corresponding pads in response to the input test signals, are scanned by corresponding, needle-shaped connections (“contact pins”) on the probe card, and relayed (e.g. via a corresponding signal line connecting the probe card with the test apparatus) to the test apparatus, where an evaluation of the corresponding signals may take place.

After the wafers have been sawn up, the components—individually available by now—may each be individually loaded into so-called carriers (i.e. into an appropriate container) and transported to a further test station.

At the further test station the carriers are inserted into a corresponding adapters and/or sockets—connected with a (further) test apparatus—whereafter the components present in each carrier are then subjected to further test procedures.

In order to test the semi-conductor components present in the carriers, the corresponding test signals generated by the test apparatus are relayed via the adapters and the carriers (and/or corresponding connections of the carriers) to the corresponding pads of the relevant semi-conductor components.

The signals emitted by the semi-conductor components at corresponding pads in response to the input test signals are scanned by corresponding carrier connections and relayed via the adapter (and a corresponding signal line connecting the adapter with the test apparatus) to the test apparatus, where an evaluation of the corresponding signals may take place.

In correspondingly similar fashion the semi-conductor components may be tested for instance after being finally installed in corresponding component housings (e.g. corresponding plug-in or surface mounted housings) or after the housings—equipped with corresponding semi-conductor components—have been installed in corresponding electronic modules, etc.

In order to achieve a high degree of accuracy in the above test procedure (in particular a high degree of accuracy in the signals used and/or measured during the above test procedure), the relevant test apparatus may be subjected—before the start of the actual test procedures—to a calibration and/or set-up process.

For instance, an appropriate calibration signal can be emitted by the relevant test apparatus onto a signal line—connecting the corresponding test apparatus with the relevant probe card, the relevant adapter (e.g. the relevant carrier or housing adapter) etc.—and the reflected signal induced by the calibration signal measured and evaluated by the test apparatus.

This process is relatively inaccurate.

Alternatively a so-called point-to-point-calibration and/or point-to-point set-up process may be used.

In this process the calibration signal emitted by the test apparatus onto the above signal line (e.g. by a corresponding calibration device) is measured and evaluated where—or approximately where—it would have been received in each case by the relevant component during the later, actual test.

In this way it can be ensured that the signals received from the relevant component by the test apparatus—during the later, actual test—correspond with the test signals required for each relevant test (with as close as possible to exactly the voltage levels required in each case and/or as close as possible to exactly the time behavior required in each case, etc.).

The testing of semi-conductor components, still present on a corresponding wafer with the aid of the above probe cards (and similarly also the calibration of the test apparatus used in each case), may take place in a sub-system (e.g. in a corresponding micro clean room system) isolated from the environment.

In order to perform the above calibration and/or set-up process, the relevant test apparatus is connected—via a corresponding signal line—with a corresponding device (movable within the sub-system) containing several (e.g. three) needle-shaped connections and/or contact pins (e.g. a SPP=short pin plate).

For calibrating the test apparatus, the SPP (short pin plate) is moved towards a calibration device (e.g. an NAC=needle auto-calibration device), in particular its NAC plate (needle auto-calibration plate) in such a way that the connections and/or contact pins of the SPP—required in each case—make contact with the connections (pads) of the calibration device (NAC) (and/or the connections of its needle plate (needle auto calibration plate)) as required in each case.

A calibration signal emitted by the test apparatus—via the above signal line—may then be measured and evaluated by the calibration device.

In correspondingly inverted fashion, a (further) calibration signal emitted by the calibration device may for instance be relayed (via a corresponding NAC pad) to the test apparatus to be measured and evaluated there.

After the calibration of the test apparatus the SPP may then again be removed from the NAC device, in particular from the NAC plate, whereafter e.g. a corresponding probe card calibration and/or set-up process may be performed. For this, the probe card (correspondingly similar to the SPP before) may be moved towards the above calibration device (NAC device, in particular its NAC plate (needle auto calibration plate)) in such a way that the connections and/or contact pins of the probe card—required in each case—make contact with the requisite connections (pads) of the calibration device in each case.

An appropriate calibration signal emitted by the calibration device (NAC device) is then relayed via a corresponding NAC pad—and a corresponding probe card contact pin in contact with it—to the probe card.

The signal emitted by the probe card to a corresponding contact pin in response to the input calibration signal, is scanned by a corresponding NAC pad—which is in contact with the contact pin—and then measured and evaluated by the calibration device.

A disadvantage of the above procedure is the high number of pad contact actions—occurring during the calibration process—with the accompanying soiling and the impossibility of any automatic cleaning.

In addition the above process cannot be executed in parallel fashion.

### SUMMARY OF THE INVENTION

The invention relates to a device, in particular a probe card, to be used in the testing of semi-conductor components, and/or a device, in particular a probe card to be used for the calibration of a semi-conductor component test system and/or a semi-conductor component test apparatus, a contact device, in particular a wafer, as well as a process to be used for the calibration of a semi-conductor component test system and/or a semi-conductor component test apparatus.

The invention is aimed at making available a novel device, in particular a probe card, as well as a novel contact device, and a novel process to be used during the calibration of a semi-conductor component test system and/or a semi-conductor component test apparatus.

### BRIEF DESCRIPTION OF THE DRAWINGS

The invention is described in more detail below with reference to the exemplary embodiments provided in the figures below, in which:

FIG. 1 shows the basic construction of a semi-conductor component test system to be used for testing semi-conductor components arranged on a wafer, with a probe card and a test apparatus connected to it.

FIG. 2 shows the basic construction of devices which—according to an embodiment example of the invention—are used for calibrating the test system shown in FIG. 1, and/or the test apparatus and/or the probe card shown there.

FIG. 3 shows a wafer—used for calibrating the test system shown in FIG. 1, and/or the test apparatus and/or the probe card shown there—viewed from the top in order to illustrate the calibration routing structures provided on the wafer.

FIG. 4 shows the probe card shown in FIG. 2, the test apparatus shown there, the calibration control device shown there and the wafer shown in FIG. 2 and 3.

### DETAILED DESCRIPTION OF THE INVENTION

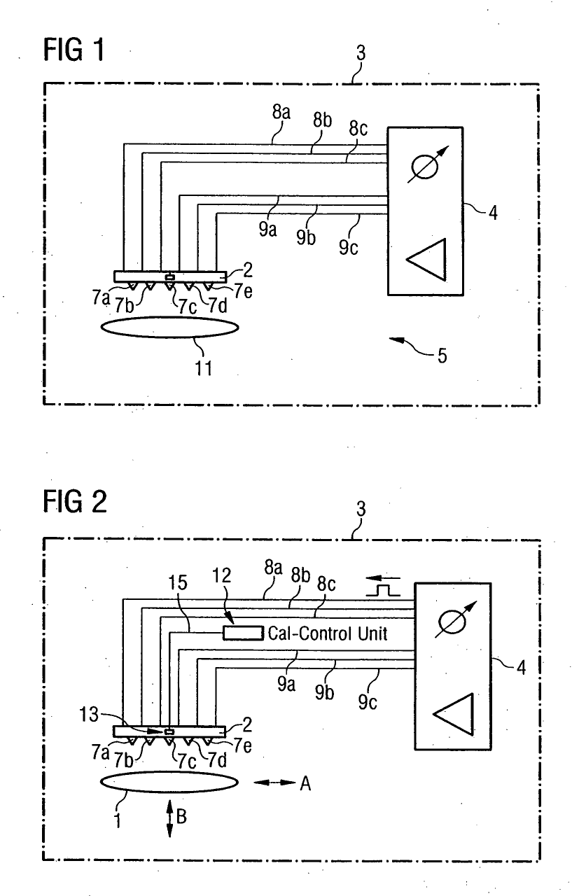

FIG. 1 shows the basic construction of a—state of the art—semi-conductor component test system 5, used at a test station 3 for testing semi-conductor components arranged and/or manufactured on a—conventional—wafer 11.

The semi-semi-conductor components to be tested and still present on the wafer 11 (i.e. on the corresponding silicon disk) may for instance be corresponding integrated (analog and/or digital) computer circuits, and/or semi-conductor memory components such as e.g. function storage components (PLAs, PALs, etc.) or table memory components (e.g. ROMs or RAMS), in particular SRAMs or DRAMs (here e.g. DRAMs (Dynamic Random Access Memories and/or dynamic Read-Write memories) with a double data rate (DDR-DRAMs=Double Data Rate DRAMs)).

The test signals required for testing the semi-conductor components—still present on the silicon disk and/or on the wafer 11—are relayed from a test apparatus 4 (here: a digital ATE test apparatus with DC function) via one or several corresponding signal lines (“driver channels” 8a, 8b, 8c) to a semi-conductor component test card and/or probe card 2, and—via corresponding contact pins 7a, 7b, 7c, 7d, 7e provided on the probe card—to corresponding connections and/or pads provided on the semi-conductor components.

As is apparent from FIG. 1 (and FIG. 2) the contact pins 7a, 7b, 7c, 7d, 7e extend downwards from the underside of the probe card 2.

The signals emitted in response to the test signals applied to corresponding (e.g. to the above or other, different) semi-conductor component connections and/or pads are—correspondingly inverted as described above—scanned by corresponding contact pins 7a, 7b, 7c, 7d, 7e of the probe card 2, and sent via the above, or one or several further signal lines (“comparator channels” 9a, 9b, 9c) to the test apparatus 4, where an evaluation of the corresponding signals may then take place.

As is apparent from FIG. 1 (and FIG. 2), the above probe card 2, the semi-conductor components (and/or the wafer 11) to be tested (as well as the above test apparatus 4 where applicable) are arranged in a sub-system isolated from the environment (e.g. a corresponding micro clean room) at test station 3.

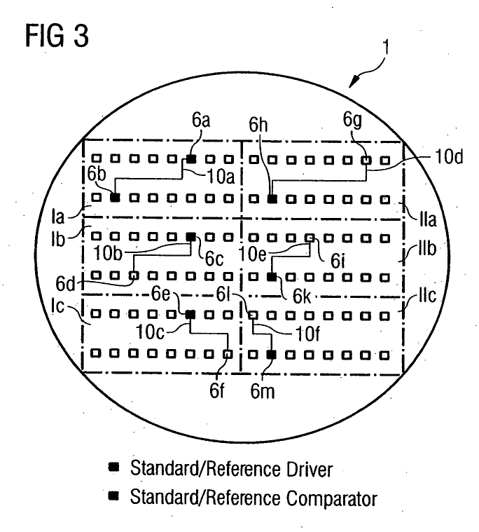

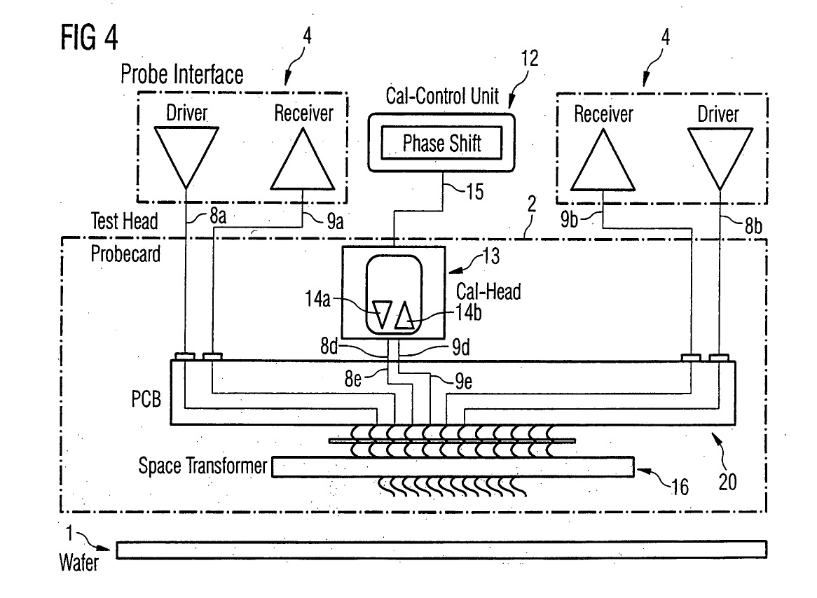

To calibrate test system 5, and/or the test apparatus 4 and/or the probe card 2 shown there (e.g. before performing the above test procedure (and/or between several test procedures performed at the above test station 3)) it is possible, in terms of an embodiment example of the invention, for instance to apply the procedure described more closely below with reference to FIG. 2, FIG. 3 and FIG. 4 (for instance with the use of a corresponding structure arranged in the micro clean room system shown in FIG. 2 and FIG. 4, and/or with the use of the special calibration wafer 1 shown in FIG. 2, FIG. 3 and FIG. 4 with the special calibration routing structures (and/or with a specially structured metallized layer) and—in particular—with the use of the—special—probe card 2 shown in FIGS. 1, 2 and 4).

As is for instance shown in FIG. 4 and is more closely illustrated below, the probe card 2 contains a calibration device (“cal head” or calibration head 13), which could for instance be firmly (and/or non-removably) built into probe card 2, and/or firmly (and/or non-removably) attached to the probe card 2.

In an alternative embodiment example the calibration device 13 (“cal head” and/or calibration head 13) could also be—removably—attached to and/or on the probe card 2.

For example, the probe card 2 could have—e.g. on its upper surface—a corresponding mechanical mounting provided with corresponding electrical plug-in connections, into which the calibration device and/or the “cal head” 13 (and/or more accurately the plug-in connection provided on it) can be inserted.

Instead of a plug-in connection (or in addition to it) any other suitable—disconnectable—mechanical connection could be used, e.g. a screwed connection and/or a clipped connection etc., etc.

Due to this feature it is possible to use one and the same calibration device 13 for numerous different test systems, for numerous different products etc.

As is further apparent from FIG. 4, the calibration device 13 includes a standard driver device 14a (“std dr.” and/or standard driver), and a standard comparator device 14b (“std cmp.” and/or standard comparator).

These are connected—for instance via pogo pins or ZIF connectors and via one or several corresponding control lines—with the test head and linked—via one or more (further) control lines 15—with a calibration control device (cal. control unit) 12.

As is more closely described below, one or several (separate) delay devices have in each case been provided in the calibration device (and/or “cal. head” 13) for the standard driver device 14a (“std. dr.” and/or standard driver), as well as for the standard comparator device 14b.

The delay device/s provided for the standard driver device 14a impose a correspondingly variably adjustable delay period—e.g. with the help of PLLs—on the signals (e.g. corresponding calibration test signals) emitted by the standard driver device 14a; in correspondingly similar fashion, the delay device/s provided for the standard comparator device 14b also impose a correspondingly variably adjustable delay period—e.g. with the help of PLLs—on the signals (e.g. corresponding calibration test signals) received by the standard comparator device 14b.

The relevant delay periods—used for the driver and/or comparator device 14a, 14b—may be adjusted and/or varied by the calibration control device 12—provided externally to the probe card 2—e.g. by the emission of corresponding delay period adjustment control signals to the control line/s 15.

As is apparent from FIG. 4, the output of the standard driver device 14a (where needed, with the above delay device/s connected in series before it) is connected via a line 8d—internally provided on probe card 2—with a PCB device 20 and via a line 8e—provided in the PCB device 20 —with a corresponding contact of an intermediate contact device—connected with a space transformer 16—and via the space transformer 16 (and a corresponding line connected with it) with one corresponding pin of the above contact pins 7a, 7b, 7c, 7d, 7e extending downwards from the underside of the probe card 2.

In correspondingly similar fashion, the input of the standard comparator device 14b (where applicable with the above delay device/s connected in series before it) is connected via a line 9d—internally provided in probe card 2—with the above PCB device 20, and via a line 9e—provided in the PCB device 20—with a corresponding contact of the intermediate contact device—connected with the space transformer 16—and via the space transformer 16 (and a corresponding line connected with it) with a corresponding further pin of the above contact pins 7a, 7b, 7c, 7d, 7e extending downwards from the underside of the probe card 2.

As is further apparent from FIG. 4, the above driver channels 8a, 8b, 8c—in each case connected with corresponding driver devices (“drivers”) in the test apparatus 4—are connected (similarly to the standard driver device 14a) via corresponding lines—internally provided in probe card 2—with the above PCB device 20, and via corresponding lines—provided in the PCB device 20 —with corresponding contacts of the intermediate contact device—connected with the space transformer 16—and via the space transformer 16 (and corresponding lines connected with it) with a corresponding further number of the above contact pins 7a, 7b, 7c, 7d, 7e—extending downwards from the underside of the probe card 2.

In correspondingly similar fashion—as is also apparent from FIG. 4—the above comparator channels 9a, 9b, 9c—in each case connected with corresponding receiver devices (“receivers”) in the test apparatus 4—via corresponding further lines—internally provided in the probe card 2—are connected with the above PCB device 20 and via corresponding further lines—provided in the PCB device 20 —with corresponding contacts of the intermediate contact device—connected with the space transformer 16—and via the space transformer 16 (and corresponding further lines connected with it) with a corresponding further number of the above contact pins 7a, 7b, 7c, 7d, 7e—extending downwards from the underside of the probe card 2.

In this way it is achieved that each tester channel (more accurately: each driver channel 8a, 8b, 8c, and each comparator channel 9a, 9b, 9c), as well as the standard driver device 14a, and the standard comparator device 14b of the calibration device 13 are electrically connected with a contact pin of the probe card 2 allocated to it in each case.

As is more closely described below, the calibration procedure used here is executed in several steps Ia, Ib, Ic, IIa, IIb, IIc, etc. for which—as shown in FIG. 3—one wafer structure field Ia, Ib, Ic, IIa, IIb, IIc (of several structure fields Ia, Ib, Ic, IIa, IIb, IIc provided on wafer 1) allocated to the relevant process step in each case is used.

In a (first) step Ia of the calibration procedure, the above delay devices (“phase shifters”) provided in the standard driver device 14a and the standard comparator device 14b of the calibration device 13, are adjusted (and in fact in relation to a particular time domain to (correspondingly similar for instance with the adjustment function used in equipment of the Type T5592 of the firm Advantest (where it is known as the “High-cal option”)).

For this, the wafer 1 is first moved (preferably automatically, i.e. by means of a suitable mechanism) towards the underside of the probe card 2 (cf. for instance the arrows A, B shown in FIG. 2), in such a way that the contact pin of the probe card 2 allocated to the standard driver 14a of the calibration device 13 and electrically connected to it, makes contact—in a (first) structure field Ia of the wafer 1—with a contact field 6a provided for the standard driver device 14a of the calibration device 13, and that a contact pin of the probe card 2 allocated to the standard comparator device 14b of the calibration device 13, and—as described above—electrically connected to it, makes contact with a contact field 6b provided for the standard comparator device 14b of the calibration device 13 in the (first) structure field Ia of the wafer 1.

As is apparent from FIG. 3, the contact field 6a provided for the standard driver device 14a—in the first structure field Ia of the wafer 1—is electrically connected via a corresponding line 10a, created by the calibration routing structure on the wafer 1, with the contact field 6b provided for the standard comparator device 14b.

Under the control of the calibration control device 12 (and/or of corresponding control signals applied to the control line/s 15) it is then arranged that a corresponding calibration test signal and/or calibration test pulse, chronologically appropriately retarded by the delay device/s provided for the standard driver device 14a, is applied by the standard driver device 14a to the above line 8d.

This signal is then relayed via the above line 8e, etc., and via the contact pins of the card 2 allocated to the standard driver device 14a, to the contact field 6a provided for the standard driver device 14a.

From the contact field 6a the calibration test signal and/or calibration test pulse signal is relayed via the above wafer line 10a to the contact field 6b provided for the standard comparator device 14b, where it is scanned by the contact pins of the card 2 allocated to the standard comparator device 14b, and relayed from there via the lines 9e, 9d etc., to the standard comparator device 14b (whereby the calibration test signal, correspondingly chronologically retarded by the delay device/s provided for the standard comparator device 14b, is entered in the standard comparator device 14b).

This procedure is repeated numerous times, and in fact in each case with a changed setting (caused by the calibration control device 12) of the delay device/s allocated to the standard driver device 14a and/or the standard comparator device 14b (i.e. with different delay periods imposed by this device in each case), until finally—correspondingly similar to the above adjustment procedure applied with the equipment of the type “T5592” of the firm Advantest as described above—the standard driver device 14a and the standard comparator device 14b (and/or their delay devices) have been adjusted to the above time domain to.

The time taken by a signal emitted by the standard driver device 14a (appropriately delayed by the delay devices allocated to the standard driver device 14a) to reach the tip of the contact pin allocated to standard driver device 14a, should then be approximately as long as the time taken for a signal applied by the standard comparator device 14b (appropriately delayed by the delay device/s allocated to the standard comparator device 14b) to travel from the tip of the contact pin allocated the standard comparator device 14b to the standard comparator device 14b itself.

As is more closely described below, an appropriate separate delay device can be provided in test apparatus 4—for each driver—and for each comparator channel 8a, 8b, 8c, 9a, 9b, 9c (and/or more accurately: for each of the driver devices (“drivers”) and for each of the receiver devices (“receivers”) provided there)—(in similar fashion as with the above standard driver device 14b, and the above standard comparator device 14b of the calibration device 13).

The delay devices provided for the driver channels 8a, 8b, 8c impose a correspondingly variably adjustable delay period on the signals (e.g. corresponding calibration test signals) emitted by the test apparatus 4 via the driver channel in question; in correspondingly similar fashion the delay devices provided for the comparator channels 9a, 9b, 9c, also impose a correspondingly variably adjustable delay period on the signals (e.g. corresponding calibration test signals) received from the test apparatus 4 via each comparator channel in question.

During a second step lb of the calibration procedure—following on the above adjustment step—the wafer 1 is first again moved (preferably again fully automatically, i.e. by means of a suitable mechanism) away from the underside of card 2, and then—after wafer 1 has been appropriately moved in a lateral direction—moved back to the underside of the card 2 (cf. the arrows A, B shown in FIG. 2), in such a way that the above contact pin of the card 2, allocated to the standard driver device 14a of the calibration device 13 and electrically connected with it, makes contact—in a (second) structure field Ib of the wafer 1—with a contact field 6c provided for the standard driver device 14a of the calibration device 13, and that a contact pin of the card 2 allocated to a ((first) non-reference) comparator channel (e.g. the comparator channel 9a), and electrically connected with it—makes contact—in the (second) structure field Ib of the wafer 1—with a contact field 6d provided for this comparator channel 9a.

As is apparent from FIG. 3, the contact field 6c provided for the standard driver device 14a of the calibration device 13—in the second structure field Ib of the wafer 1 —is electrically connected with the contact field 6d provided for the ((first) non-reference) comparator channel 9a via a corresponding line 10b, created by the calibration routing structure on the wafer 1.

A calibration test signal and/or calibration test pulse, emitted to the above line 8d (under the control of the calibration control device 12) by the standard driver device of the calibration device 13 at a particular point of time to (selected in relation to a particular time domain t₀—e.g. one appropriately adjusted as described above—and/or to a reference pulse (e.g. to its positive flank))—and appropriately chronologically retarded by the delay device provided for the driver device 14a—is relayed via the above line 8e and the contact pin of the probe card 2 allocated to the standard driver device 14a of the calibration device 13 to the contact field 6c provided for the standard driver device 14a of the calibration device 13.

From the contact field 6c the calibration test signal and/or calibration test pulse signal is relayed via the above wafer line 10b to the contact field 6d provided for the comparator channel 9a, where it is scanned by the contact pin of the card 2 allocated to the comparator channel 9a and led, at a point of time t_{x,1,1} ((“test signal input point of time”) that can be related e.g. to the reference pulse (e.g. its positive flank) and delayed in relation to the output point of time of the above calibration test signal as a result of the signal duration) via the above comparator channel 9a, to the test apparatus 4 (whereby the calibration test signal is entered into the test apparatus 4, correspondingly chronologically retarded by means of a corresponding delay device provided for the comparator channel 9a).

In test apparatus 4 the test signal input point of time t_{x,1,1} of the calibration test signal, sent via the comparator channel 9a and correspondingly retarded by the corresponding delay device, is measured (for example by measuring the time elapsed since the last positive flank of the reference pulse) and compared with a reference point of time tₓ—predetermined (also in relation to the above time domain t₀, and/or e.g. the positive flank of the reference pulse)(calibration process sub-step Ib, 1).

If the value of the test signal input point of time t_{x,1,1} is higher than the value of the reference point of time tₓ, the delay period generated by the delay device allocated to the comparator channel 9a is correspondingly reduced.

If however the value of the test signal input point of time t_{x,1,1} is lower than the value of the reference point of time tₓ, the delay period generated by the delay device allocated to the comparator channel 9a is correspondingly increased.

Then a corresponding calibration test signal and/or calibration test pulse signal, correspondingly (identically) chronologically retarded by the corresponding delay device, is again applied by the standard driver device 14a of the calibration device 13 (under the control of the calibration control device 12) to the above line 8d (at a correspondingly identical point of time t₀, e.g. selected in relation to the above time domain t₀, and/or in relation to the reference pulse (e.g. its positive flank) as above) and led via line 8e, and the contact pin of the probe card 2 allocated to the standard driver device 14a of the calibration device 13, the contact field 6c provided for the standard driver device 14a of the calibration device 13, the wafer line 10b, the contact field 6d provided for the above comparator channel 9a, the contact pin of the probe card 2 allocated to the comparator channel 9a and the comparator channel 9a to the test apparatus 4 (whereby the calibration test signal, chronologically retarded to a greater or lesser degree than before by the corresponding delay device provided for the comparator channel 9a, is entered into the test apparatus 4 at a test signal input point of time t_{x,1,2}).

In test apparatus 4 the test signal input point of time t_{x,1,2} of the calibration test signal, sent via the comparator channel 9a and correspondingly retarded by the corresponding delay device, is measured (for example by measuring the time elapsed since the last positive flank of the reference pulse) and compared with the—predetermined—reference point of time tₓ (calibration process sub-step Ib, 2)

If the value of the test signal input point of time t_{x,1,2} is higher than the value of the reference point of time tₓ, the delay period generated by the delay device allocated to the comparator channel 9a is correspondingly reduced.

If however the value of the test signal input point of time t_{x,1,2} is lower than the value of the reference point of time tₓ, the delay period generated by the delay device allocated to the comparator channel 9a is correspondingly increased.

Then a corresponding calibration test signal and/or calibration test pulse signal is again applied by the standard driver device 14a of the calibration device 13 to line 8d, and in test apparatus 4 the test signal input point of time t_{x,1,3}, of the calibration test signal, fed back by the comparator channel 9a and correspondingly delayed by the corresponding delay device, is measured and compared with the—predetermined—reference—point of time tₓ, etc., etc. until it is determined that the test signal input point of time and the reference point of time tₓ are identical and/or essentially identical (calibration process sub-step Ib, 3).

The delay period t_{delay,1,1} (and/or the relevant setting of the delay device's characteristic data) determined for the delay device allocated to the comparator channel 9a is then stored in a corresponding storage facility of the test apparatus 4, etc. (calibration process sub-step Ib, 4).

This delay period (and/or the setting of the delay device allocated to it) may be fixed as the standard delay period and/or standard setting for the corresponding delay device for the normal operation (during the testing of components) of the corresponding test apparatus 4.

Next a further (main) step Ic of the calibration procedure can be executed.

Hereby the wafer 1 is first again moved (preferably fully automatically, i.e. by means of a suitable mechanism) away from the underside of card 2, then moved in a lateral direction and finally to the underside of the card 2 (cf. the arrows A, B shown in FIG. 2), in such a way that the contact pin of the card 2, allocated to the standard driver device 14a of the calibration device 13 and electrically connected with it, makes contact—in a (third) structure field Ic of the wafer 1—with a contact field 6e provided for the standard driver device 14a of the calibration device 13, and that a contact pin of the card 2 allocated to a ((further) non-reference) comparator channel 9b and electrically connected with it—makes contact—in the (third) structure field Ic of the wafer 1—with a contact field 6f provided for this comparator channel 9b.

As is apparent from FIG. 3, the contact field 6e provided for the standard driver device 14a of the calibration device 13—in the third structure field Ic of the wafer 1—is electrically connected with the contact field 6f provided for the (non-reference) comparator channel 9b via a corresponding line 10c, created by the calibration routing structure on the wafer 1.

Next corresponding calibration process sub-steps may be executed numerous times in succession—for the (non-reference) comparator channel 9b—as described above for the non-reference comparator channel 9a in terms of the calibration process subs-steps Ib, 1-Ib, 4 (e.g. calibration process sub-steps—repeated numerous times in succession—corresponding with the above calibration process sub-steps Ib, 1-Ib, 4).

Hereby—corresponding with that described above—a delay period can be determined for the (non-reference) comparator channel 9b and/or the delay device allocated to it, for which the test signal input point of time and the reference point of time tₓ are identical and/or essentially identical.

This delay period (and/or the setting of the delay device allocated to it) may be fixed as the standard delay period and/or standard setting for the corresponding delay device for the normal operation of the corresponding test apparatus 4 (during the testing of components).

The steps corresponding with the above process steps Ib, Ic (with calibration process sub-steps, corresponding with the above calibration process sub-steps Ib, 1, Ib, 4, executed numerous times in succession) are executed—with the use of the above standard driver device 14a of the calibration device 13—for all (non-reference) comparator channels.

Next (or alternatively even before the above process steps Ib, Ic) the process steps IIa, IIb, etc.—corresponding with the above process steps Ib, Ic—are correspondingly executed with the use of the standard comparator device 14b of the calibration device 13 (instead of with the standard driver device 14a of the calibration device 13) for the above driver channels 8a, 8b (instead of for the comparator channels 9a, 9b):

For example, during a process step IIa of the calibration process of wafer 1—e.g. executed directly after the above process steps 1b, 1c—the wafer 1 is moved (preferably automatically, i.e. by means of a suitable mechanism) towards the underside of the probe card 2 (cf. for instance the arrows A, B shown in FIG. 2), in such a way that the contact pin of the probe card 2 allocated to the ((first) non-reference) driver channel 8a and electrically connected to it, makes contact—in a (fourth) structure field IIa of the wafer 1—with a contact field 6g provided for the driver channel 8a, and that a contact pin of the probe card 2 allocated to the standard comparator device 14b of the calibration device 13 and electrically connected with it, makes contact—in the (fourth) structure field IIa of the wafer 1—with a contact field 6h provided for the standard comparator device 14b of the calibration device 13.

As is apparent from FIG. 3, the contact field 6g provided for the driver channel 8a—in the fourth structure field IIa of the wafer 1—is electrically connected with the contact field 6h provided for the standard comparator device 14b of the calibration device 13 via a corresponding line 10d, created by the calibration routing structure on the wafer 1.

A calibration test signal and/or calibration test pulse, applied to driver channel 8a (at a particular point of time to (e.g. selected in relation to the above time domain t₀ and/or in relation to a reference pulse (e.g. to its positive flank)), emitted by the test apparatus 4, appropriately chronologically delayed by a delay device provided for the driver channel 8a, is relayed via the driver channel 8a and the contact pin of the probe card 2 allocated to it, to the contact field 6g provided for the driver channel 8a.

From the contact field 6g the calibration test signal and/or calibration test pulse signal is relayed via the above wafer line 10d to the contact field 6h provided for the standard comparator device 14b of the calibration device 13, where it is scanned by the contact pins of the card 2 allocated to the standard comparator device 14b of the calibration device 13 and led, at a point of time t_{x,4,1} ((“test signal input point of time”) that can be related e.g. to the reference pulse (e.g. to its positive flank) and delayed in relation to the output point of time of the above calibration test signal as a result of the signal duration) via the lines 9e, 9d, to the standard comparator device 14b of the calibration device 13 (whereby the calibration test signal is entered into the standard comparator device 14b, correspondingly chronologically retarded by means of a corresponding delay device provided for the comparator device 14b of the calibration device 13).

Then the test signal input point of time t_{x,4,1} of the calibration test signal, fed in and correspondingly retarded by the corresponding delay device, is measured (for example by measuring the time elapsed since the last positive flank of the reference pulse) and compared with a—predetermined—reference point of time tₓ (also related to the above time domain t₀, e.g. to the positive flank of the reference pulse and identical with the above reference point of time)(calibration process sub-step IIa, 1).

If the value of the test signal input point of time t_{x,4,1} is higher than the value of the reference point of time tₓ, the delay period generated by the delay device allocated to the driver channel 8a is correspondingly reduced.

If however the value of the test signal input point of time t_{x,4,1} is lower than the value of the reference point of time tₓ, the delay period generated by the delay device allocated to the driver channel 8a is correspondingly increased.

Then a corresponding calibration test signal and/or calibration test pulse signal, correspondingly varied in strength, e.g. chronologically retarded more or less strongly than before by the corresponding delay device, is again applied (at a correspondingly identical point of time t₀, e.g. selected in relation to the above time domain t₀, and/or in relation to the reference pulse (e.g. its positive flank) as above) to the driver channel 8a by the test apparatus 4 and led via the driver channel 8a and the contact pin of the card 2 allocated to it, the contact field 6g provided for the driver channel 8a, the wafer line 10d, the contact field 6h allocated to the standard comparator device 14b of the calibration device 13, the contact pin of the card 2 allocated to the standard comparator device 14b of the calibration device 13, and the above lines 9e, 9d, to the standard comparator device 14b of the calibration device 13.

Then the test signal input point of time t_{x,4,2} of the calibration test signal, fed in and correspondingly retarded by the corresponding delay device, is measured (for example by measuring the time elapsed since the last positive flank of the reference pulse) and compared with the—predetermined—reference point of time tₓ (calibration process sub-step IIa, 2)

If the value of the test signal input point of time t_{x,4,2} is higher than the value of the reference point of time tₓ, the delay period generated by the delay device allocated to the driver channel 8a is correspondingly reduced.

If however the value of the test signal input point of time t_{x,4,2} is lower than the value of the reference point of time tₓ, the delay period generated by the delay device allocated to the driver channel 8a is correspondingly increased.

Then a new corresponding calibration test signal and/or calibration test pulse signal is applied to driver channel 8a by the test apparatus 4 and the test signal input point of time t_{x,4,3} of the calibration test signal, fed back via lines 9e, 9d, is measured in the test apparatus 4 and compared with the—predetermined—reference point of time tₓ etc., etc. until it has been determined that the test signal input point of time and the reference point time tₓ are identical or essentially identical (calibration process sub-step IIa, 3)

The delay period t_{delay,4,1} (and/or the current setting of the data characterizing the delay device) imposed by the delay device allocated to the driver channel 8a, is stored in a corresponding storage device of the test apparatus 4 (calibration process sub-step IIa, 4).

This delay period (and/or the setting of the delay device allocated to it) may be fixed as the standard delay period and/or standard setting for the corresponding delay device for the normal operation of the test apparatus 4 (during the testing of components).

The steps IIb, IIc, etc. (with the calibration process sub-steps executed numerous times in succession and corresponding with the above calibration process sub-steps IIa, 1-IIa, 4) corresponding with the above process step IIa, are executed—with the use of the above standard comparator device 14a of the calibration device 13—for all (non-reference) driver channels 8b, 8c, etc. (in each case with the use of corresponding further wafer structure fields IIb, IIc, etc., allocated to each of the process steps IIb, IIc, etc.).

Hereby—as illustrated above—delay periods, for which the test signal input point of time and the reference point of time tₓ are identical and/or essentially identical, can be determined for the remaining (non-reference) driver channels 8b, 8c, and/or the delay devices allocated to them.

The delay periods determined in this way (and/or the settings of the corresponding delay devices allocated to them) may be fixed as the standard delay period and/or standard setting for the corresponding delay devices for the normal operation of the test apparatus 4 (during the testing of components).

Advantageously the driver channels 8a, 8b, 8c, and/or the comparator channels 9a, 9b, 9c, shown in FIG. 2, should all be of the same length, and/or the lengths of the above wafer lines 10a, 10b, 10c, 10d, 10e, 10f should all be essentially the same.

With the above process and system a probe card—and/or test apparatus—calibration delivering a relatively high degree of accuracy—is produced, which is independent of the probe card 2 applied in each case, and whereby the total time period required for the calibration can be kept relatively brief.

In an alternative embodiment example—instead of one calibration device 13 (“cal head” and/or calibration head 13)—several (e.g. two, three, or four, or more than six or eight, e.g. sixteen etc. “cal heads”, correspondingly similarly or identically constructed and arranged to the calibration device 13) could also be (removably or non-removably) attached to or on the probe card 2, which cal heads—as with the calibration device 13—could in each case be connected with a calibration control device (corresponding with the calibration device 12 (or for instance with a central control device)).

With the calibration devices several (e.g. two, three, or four, or more than six or eight, e.g. sixteen) driver channels and/or comparator channels may then be calibrated—in parallel or simultaneously—at any one time.

In this way the time required for the calibration can be further reduced.

### REFERENCE NUMBERS

1 Calibration Wafer
2 Probe card
3 Test station
4 Test apparatus
5 Test system
6a Contact field
6b Contact field
6c Contact field
6d Contact field
6e Contact field
6f Contact field
6g Contact field
6h Contact field
6i Contact field
6k Contact field
6l Contact field
6m Contact field
7a Contact pins
7b Contact pins
7c Contact pins
7d Contact pins
7e Contact pins
8a Driver channel
8b Driver channel
8c Driver channel
8d Line
8e Line
9a Comparator channel
9b Comparator channel
9c Comparator channel
9d Line
9e Line
10a Line
10b Line
10c Line
10d Line
10e Line
10f Line
11 Wafer
12 Calibration control device
13 Calibration device
14a Standard driver device
14b Standard comparator device
15 Control line
16 Space transformer
20 PCB device
Ia Structure field
Ib Structure field
Ic Structure field
IIa Structure field
IIb Structure field
IIc Structure field

What is claimed is:

1. A device configured to test semi-conductor components, comprising:
at least one contact element for contacting corresponding semi-conductor components, arranged on a wafer; and
at least part of a calibration device configured to calibrate a semi-conductor component test system and/or a semi-conductor component test apparatus.

2. The device according to claim 1, wherein the calibration device comprises a standard and/or reference comparator device for receiving test signals emitted by a test apparatus connected with the device.

3. The device according to claims 1, wherein the calibration device comprises a standard and/or reference driver device for sending test signals to a test apparatus connected with the device.

4. The device according to claim 1, wherein the at least part of a calibration device are connected to the device in a fixed and non-removable fashion.

5. The device according to claim 1, wherein the at least part of a calibration device are connected to the device in a removable fashion.

6. The device according to claim 5, wherein the at least part of a calibration device are connected with the device by means of a disconnectable plug-in connection.

7. The device according to claim 5, wherein the at least part of a calibration device are connected with the device by means of a disconnectable clipped connection.

8. The device according to claim 5, wherein the at least part of a calibration device are connected with the device by means of a disconnectable screw connection.

9. The device according to claim 1, wherein the at least one contact element is a contact pin.

10. A device configured to calibrate a semi-conductor component test system and/or a semi-conductor component test apparatus, comprising:
at least one contact element; and
at least part of a calibration device configured to calibrate the semi-conductor component test system and/or the semi-conductor component test apparatus.

11. A contact device configured for calibration of a semi-conductor component test apparatus and/or a semi-conductor component test system, comprising:
a first connection, at which a corresponding signal can be entered; and
a second connection, connected or connectable with the first connection, at which the signal can be emitted.

12. The contact device according to claim 11, configured such that, in a first setting of a device, a first contact element of the device, connected or connectable with a standard and/or reference driver device of the calibration device, contacts the first connection, and a second contact element of the device, connected or connectable with a standard and/or reference comparator device of the calibration device, contacts the second connection.

13. A system, which comprises:
a contact device configured for calibration of a semi-conductor component test apparatus and/or a semi-conductor component test system, including a first connection, at which a corresponding signal can be entered, and a second connection, connected or connectable with the first connection, at which the signal can be emitted; and
a device configured to test semi-conductor components, including at least one contact element for contacting corresponding semi-conductor components, arranged on a wafer, and at least part of a calibration device configured to calibrate a semi-conductor component test system and/or a semi-conductor component test apparatus.

14. A process to be used in the calibration of a semi-conductor component test system and/or of a semi-conductor component test apparatus, comprising:
emitting a signal at a driver channel of a semi-conductor component test apparatus; and
relaying the signal to a probe card, wherein the probe card comprises a standard and/or reference comparator device, which receives the signal.

15. A process to be used for the calibration of a semi-conductor component test system and/or a semi-conductor component test apparatus, comprising:
relaying a signal from a probe card to a comparator channel of a semi-conductor component test apparatus, wherein
the probe card comprises a standard and/or reference driver device, which emits the signal.
